(19) United States
(12) Patent Application Publication
(10) Pub. No.: US 2026/0367581 A1
(43) Pub. Date: Nov. 19, 2026

(54) TIME-TO-DIGITAL CONVERSION DEVICE

(71) Applicant: Taiwan Semiconductor Manufacturing Company, Ltd., Hsinchu (TW)

(72) Inventors: Tsung-Che LU, Tainan (TW); Chin-Ming FU, Zhubei (TW); Chih-Hsien CHANG, Taipei (TW)

(73) Assignee: Taiwan Semiconductor Manufacturing Company, Ltd., Hsinchu (TW)

(21) Appl. No.: 19/750,637

(22) Filed: Jul. 22, 2026

Related U.S. Application Data
(63) Continuation of application No. 19/017,719, filed on Jan. 12, 2025.
(60) Provisional application No. 63/703,789, filed on Oct. 4, 2024.

(51) Int. Cl. G04F 10/00; H03L 7/097; H03L 7/099; H03M 1/38

(52) U.S. Cl. CPC G04F 10/005; H03L 7/097; H03L 7/0995; H03M 1/38

(57) ABSTRACT

A time-to-digital conversion device embodiment includes a first oscillator configured to output a first clock signal in response to a first event and a second oscillator configured to output a second clock signal in response to a second event. The time-to-digital conversion device embodiment further includes a phase detector configured to generate a detection signal based on a phase relationship between the first clock signal and the second clock signal, and a clock counter configured to generate a count value based on the first clock signal in response to the detection signal indicating that a phase of the second clock signal lags behind a phase of the first clock signal. The count value is indicative of a time difference between the first event and the second event.

### PRIORITY CLAIMS AND CROSS-REFERENCE

This patent application is a continuation of U.S. patent application Ser. No. 19/017,719, filed Jan. 12, 2025, which claims the benefit of U.S. Provisional Patent Application No.: 63/703,789 filed on Oct. 4, 2024, the entire disclosures of which are hereby incorporated by reference.

### BACKGROUND

A time-to-digital conversion device, such as a time-to-digital converter (TDC), is configured to convert time information to digital values. In some applications, a time-to-digital conversion device in conjunction with a voltage-to-timing converter (VTC) can be used to sense a waveform on an integrated circuit (IC) die in order to monitor a power integrity (PI) characteristic of the IC die. In some applications, a time-to-digital conversion device can be used to measure a phase noise of a phase-locked loop (PLL). In some applications, a time-to-digital conversion device can be used to measure a time-of-flight (ToF) of a wireless signal, an acoustic signal, and/or an optical signal.

In some applications with respect to measuring waveforms with good precision and flexibility, a time-to-digital conversion device with sub-100-femtosecond (fs) resolution and a large dynamic range may be used. In some applications, an area budget for implementing a time-to-digital conversion device may limit the resolution and/or the dynamic range of the time-to-digital conversion device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B are block diagrams of application examples based on a time-to-digital conversion device, in accordance with some embodiments.

FIG. 2 is a block diagram of a time-to-digital conversion device example, in accordance with some embodiments.

FIG. 3 is a process flow diagram of a process flow example performed by a time-to-digital conversion device, in accordance with some embodiments.

FIG. 4A is a circuit diagram of an oscillator example, in accordance with some embodiments.

FIG. 4B is a circuit diagram of the NAND gate in the delay circuit in FIG. 4A, in accordance with some embodiments.

FIG. 5 is a circuit diagram of a phase detector example, in accordance with some embodiments.

FIG. 6A is a circuit diagram of a clock gating circuit example, in accordance with some embodiments.

FIGS. 6B-6C are circuit diagrams of variation examples based on the clock gating circuit in FIG. 6A, in accordance with some embodiments.

FIG. 7 is a block diagram of a counter example, in accordance with some embodiments

FIGS. 8A-8D are diagrams of signal waveforms and/or digital values of a time-to-digital conversion session example by a time-to-digital conversion device that is based on the examples in FIGS. 2-6A and 7, in accordance with some embodiments.

FIGS. 9A-9B are diagrams of a delay circuit example based on a phase interpolator, in accordance with some embodiments.

FIGS. 10A-10C are diagrams of a delay circuit example based on an adjustable load resistance, in accordance with some embodiments.

FIG. 11 is a circuit diagram of oscillators that are configured to correspond to different clock periods, in accordance with some embodiments.

FIG. 12 is a flowchart of a method of generating a count value indicative of a time difference between a first event and a second event, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

Recent developments in computer technology have resulted in an increased demand for computing power. For example, artificial intelligence (AI) is now more powerful than ever with advanced large language models that have numerous parameters. The training of the large language models and/or the inference operations based on the large language models require a large amount of computing power, which has increased the need for high-performance computing (HPC) devices. Processing circuitry and components, such as central processing units (CPUs), graphical processing units (GPUs), and/or tensor processing units (TPUs), in an HPC device face challenges with power integrity due to heavy currents, which are addressable based on monitoring the power impedance of the processing circuitry and components.

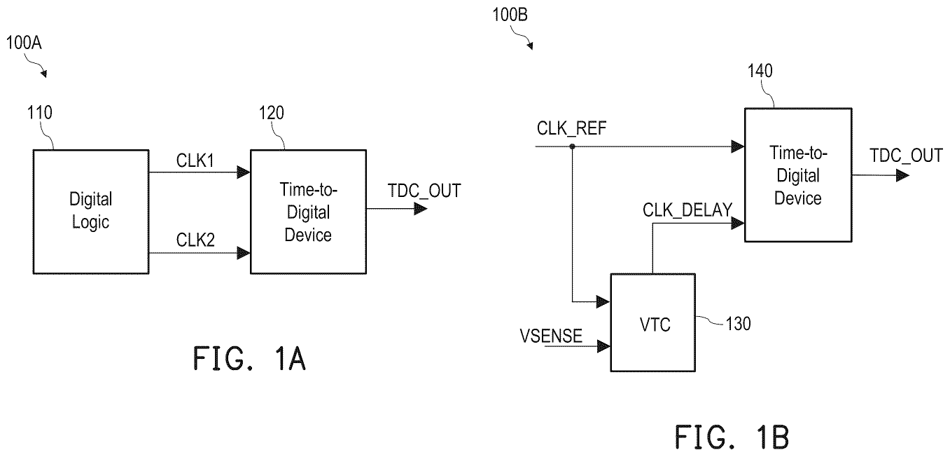

In some applications, monitoring the power impedance includes monitoring on-chip waveforms or signal delays with respect to a reference signal. For example, FIG. 1A is a block diagram 100A of a first application example for determining a clock skew inside digital logic 110 in an integrated circuit die, in accordance with some embodiments. In FIG. 1A, two clock signals CLK1 (e.g., a reference signal) and CLK2 (e.g., a monitored signal) output by digital logic 110 are coupled to a time-to-digital conversion device 120 for comparison. In this example, the time-to-digital conversion device 120 is configured to generate an output signal TDC_OUT based on clock signals CLK1 and CLK2, where output signal TDC_OUT represents a value (e.g., a multi-bit digital data) that is indicative of a time difference between clock signal CLK1 and clock signal CLK2.

Also, FIG. 1B is a block diagram 100B of a second application example for sensing a voltage level of a waveform in an integrated circuit die, in accordance with some embodiments. In FIG. 1B, a voltage signal VSENSE is picked up by a voltage-to-time converter (labeled “VTC”) 130. Based on a reference clock signal CLK_REF, voltage-to-time converter 130 generates a delay signal CLK_DELAY, such that the voltage level of voltage signal VSENSE is converted into a time difference between reference clock signal CLK_REF and delay signal CLK_DELAY. In this example, a time-to-digital conversion device 140 is configured to generate an output signal TDC_OUT based on reference clock signal CLK_REF and delay signal CLK_DELAY, where output signal TDC_OUT represents a value (e.g., a multi-bit digital data) that is indicative of a time difference between reference clock signal CLK_REF and delay signal CLK_DELAY.

In some applications, a time-to-digital conversion device based on a Vernier delay line configuration is capable of achieving a fine resolution (e.g., sub-100-femtosecond (fs)), at the cost of increased delay stages, area, complexity, and hence costs.

The present disclosure describes in one or more embodiments a time-to-digital conversion device that is based on a clock period difference between two oscillators. In some embodiments, two oscillators are activated in response to two events, and a later activated clock signal chases an earlier activated clock signal in an increment of the clock period difference per clock cycle. In some embodiments, without scaling up the number of delay stages, the configuration according to one or more embodiments of the present application still has a fine resolution in the time domain (e.g., sub-80-femtosecond resolution) and a measurable range from 0 to 245 picoseconds, which in turns improves the landscape efficiency in an integrated circuit die, reduces circuitry complexity, and reduces manufacturing costs.

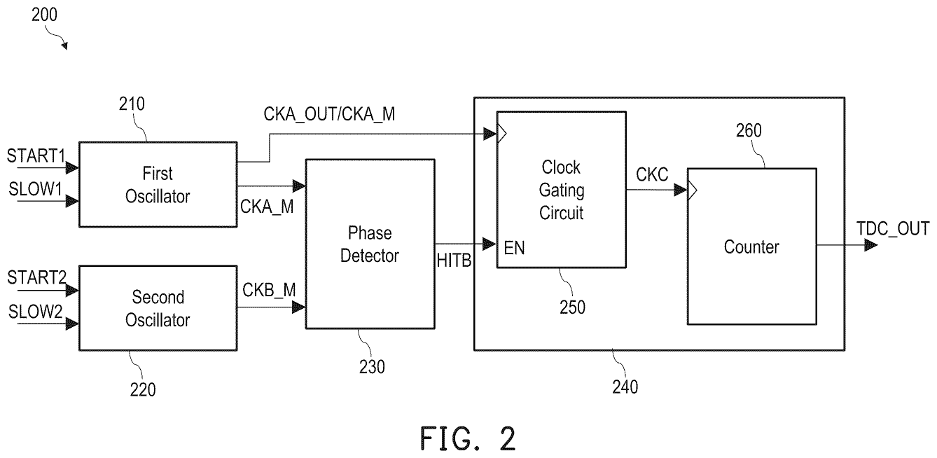

FIG. 2 is a block diagram of a time-to-digital conversion device 200, in accordance with some embodiments. Time-to-digital conversion device 200 in FIG. 2 is illustrated as a non-limiting example. In some embodiments, some components of time-to-digital conversion device 200 are simplified or omitted in FIG. 2.

In FIG. 2, time-to-digital conversion device 200 includes a first oscillator 210, a second oscillator 220, a phase detector 230, and a clock counter 240. First oscillator 210 is configured to receive a first reference signal START1 and a first slow down control signal SLOW1. First oscillator 210 is configured to output a first clock signal CKA_M in response to a first event. In some embodiments, first oscillator 210 is further configured to output a first buffered clock signal CKA_OUT that is derived based on first clock signal CKA_M passing a buffer stage of the first oscillator 210. In some embodiments, first clock signal CKA_M and first buffered clock signal CKA_OUT have a first clock period T1.

Also, second oscillator 220 is configured to receive a second reference signal START2 and a second slow down control signal SLOW2. Second oscillator 220 is configured to output a second clock signal CKB_M in response to a second event. In some embodiments, the second clock signal CKB_M has a second clock period T2. In some embodiments, the first event occurs before the second event. In some embodiments, the first clock period T1 is greater than the second clock period T2. In some embodiments, second clock period T2 is at least 100 times a period difference ΔT between first clock period T1 and second clock period T2. In some embodiments, second clock period T2 ranges from 2 nanoseconds (ns) to 6 ns. In some embodiments, the period difference ΔT ranges from 60 femtoseconds (fs) to 100 fs.

In some embodiments, as a non-limiting example, the first event corresponds to first reference signal START1 changing or transitioning from a first logic state (e.g., logic LOW, or LOW in this disclosure) to a second logic state (e.g., logic HIGH, or HIGH in this disclosure). In some embodiments, the second event corresponds to second reference signal START2 changing or transitioning from the first logic state (e.g., LOW) to the second logic state (e.g., HIGH). In some embodiments, first oscillator 210 is configured to be deactivated based on first reference signal START1 being at the first logic state and to be activated based on first reference signal START1 being at the second logic state. In some embodiments, second oscillator 220 is configured to be deactivated based on second reference signal START2 being at the first logic state and to be activated based on second reference signal START2 being at the second logic state.

In some embodiments, first clock period T1 is adjustable based on first slow down control signal SLOW1, and second clock period T2 is adjustable based on second slow down control signal SLOW2. In some embodiments, first oscillator 210 and second oscillator 220 are based on the same hardware configuration. In some embodiments, first oscillator 210 is a first ring oscillator that includes one or more of a first load capacitance, a first load resistance, or a first phase interpolator between two consecutive inverting stages of first oscillator 210 and configured to set a first configurable delay of first oscillator 210. In some embodiments, second oscillator 220 is a second ring oscillator that includes one or more of a second load capacitance, a second load resistance, or a second phase interpolator between two consecutive inverting stages of second oscillator 220 and configured to set a second configurable delay of second oscillator 220. In some embodiments, first clock period T1 is determinable based on the first configurable delay of first oscillator 210, and second clock period T2 is determinable based on the second configurable delay of second oscillator 220.

During operation of time-to-digital conversion device 200, first clock period T1 and second clock period T2 are set based on first slow down control signal SLOW1 and second slow down control signal SLOW2. For example, during operation, first slow down control signal SLOW1 is set to the second logic state (e.g., HIGH) indicating that first clock period T1 corresponds to a slower clock setting of first oscillator 210 (e.g., setting the first configurable delay to a greater value), while second slow down control signal SLOW2 is set to the first logic state (e.g., LOW) indicating that second clock period T2 corresponds to a faster clock setting of second oscillator 220 (e.g., setting the second configurable delay to a smaller value).

In yet some alternative embodiments, first oscillator 210 and second oscillator 220 are based on different hardware configurations corresponding to outputting clock signals having first clock period T1 and second clock period T2, respectively. In some embodiments, no adjustable delays are available based on the hardware configurations of first oscillator 210 and second oscillator 220, and first slow down control signal SLOW1 and/or second slow down control signal SLOW2 are thus omitted.

Phase detector 230 is configured to generate a detection signal HITB based on a phase relationship between first clock signal CKA_M and second clock signal CKB_M. In some embodiments, as a non-limiting example, detection signal HITB has the first logic state (e.g., LOW) indicating that a phase of first clock signal CKA_M lags behind a phase of second clock signal CKB_M, and has the second logic state (e.g., HIGH) indicating that the phase of second clock signal CKB_M lags behind the phase of first clock signal CKA_M.

Clock counter 240 is configured to generate a count value TDC_OUT based on first clock signal CKA_M in response to detection signal HITB indicating that the phase of second clock signal CKB_M lags behind the phase of first clock signal CKA_M. In some embodiments, count value TDC_OUT is indicative of a time difference between the first event and the second event. In some embodiments, clock counter 240 is configured to receive and count the clock cycles of first clock signal CKA_M. In some embodiments, clock counter 240 is configured to receive and count the clock cycles of first buffered clock signal CKA_OUT. In yet some other embodiments, instead of first clock signal CKA_M or first buffered clock signal CKA_OUT, clock counter 240 is configured to generate count value TDC_OUT based on second clock signal CKB_M in response to detection signal HITB indicating that the phase of second clock signal CKB_M lags behind the phase of first clock signal CKA_M.

In FIG. 2, clock counter 240 includes a clock gating circuit 250 and a counter 260. In some embodiments, clock gating circuit 250 is configured to generate a count clock signal CKC based on first clock signal CKA_M (or first buffered clock signal CKA_OUT derived from first clock signal CKA_M) and detection signal HITB. In some embodiments, clock gating circuit 250 is configured to generate count clock signal CKC that has the same frequency and period as first clock signal CKA_M in response to detection signal HITB being at the second logic state (e.g., HIGH) indicating that the phase of second clock signal CKB_M lags behind the phase of first clock signal CKA_M. In some embodiments, clock gating circuit 250 is configured to set count clock signal CKC at a logic state (e.g., the first logic state or LOW) in response to detection signal HITB being at the first logic state (e.g., LOW). In this example, clock gating circuit 250 includes a clock terminal (depicted with a triangle mark) configured to receive first clock signal CKA_M or first buffered clock signal CKA_OUT, an enable terminal (labeled with “EN”) configured to receive detection signal HITB, and an output terminal configured to output count clock signal CKC.

In some embodiments, counter 260 is an N-bit counter, and TDC_OUT is a count value that is an N-bit unsigned integer. In some embodiments, N ranges from 6 to 12, or from 8 to 10. In this example, counter 260 includes a clock terminal (depicted with a triangle mark) configured to receive count clock signal CKC, and an output terminal configured to output count value TDC_OUT.

In some embodiments, an integrated circuit die includes one or more digital circuit blocks configured to output various reference signals (e.g., first reference signal START1 and second reference signal START2). In some embodiments, the integrated circuit die further includes time-to-digital conversion device 200 configured to output a count value (e.g., count value TDC_OUT) indicative of a time difference between a first event based on the first reference signal and a second event based on the second reference signal.

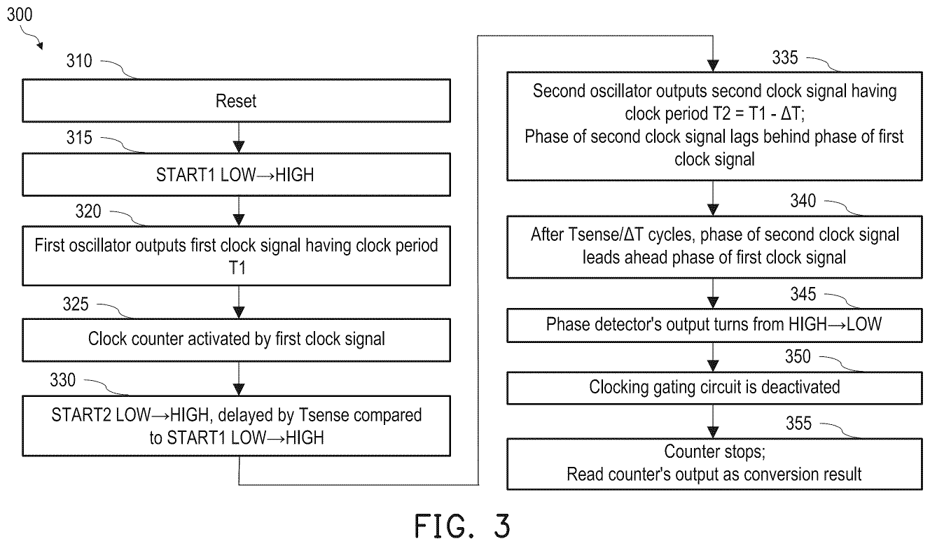

FIG. 3 is a process flow diagram of a process flow 300 performed by a time-to-digital conversion device, in accordance with some embodiments. In some embodiments, process flow 300 is illustrated based on various operations performed by time-to-digital conversion device 200 in FIG. 2 as a non-limiting example. In FIG. 3, process flow 300 includes stages 310-355.

At stage 310, various components of the time-to-digital conversion device are reset. For example, phase detector 230, clock gating circuit 250, and counter 260 are reset to clear any data or logic states from a previous time-to-digital conversion session. At stage 310, detection signal HITB is set to deactivate clock gating circuit 250, and count clock signal CKC is set to cause no action at counter 260.

At stage 315, a first reference signal (e.g., first reference signal START1) changes from a first logic state (e.g., LOW) to a second logic state (e.g., HIGH), and the transition of logic state indicates the occurrence of a first event. At stage 320, a first oscillator (e.g., first oscillator 210) outputs a first clock signal (e.g., first clock signal CKA_M) as an oscillating signal in response to the first event. In some embodiments, first clock signal CKA_M has a first clock period T1.

At stage 325, based on the presence of first clock signal CKA_M (as an oscillating signal) and absence of second clock signal CKB_M (as an oscillating signal), phase detector 230 starts to output detection signal HITB at the first logic state (e.g., LOW) indicating that a phase of second clock signal CKB_M lags behind a phase of first clock signal CKA_M, which in turn activates clock gating circuit 250 and then activates counter 260.

At stage 330, a second reference signal (e.g., second reference signal START2) changes from the first logic state (e.g., LOW) to the second logic state (e.g., HIGH), and the transition of logic state indicates the occurrence of a second event. In some embodiments, the transition of logic state of second reference signal START2 from LOW to HIGH is delayed by a time difference Tsense compared to the transition of logic state of first reference signal START1 from LOW to HIGH. At stage 335, a second oscillator (e.g., second oscillator 220) outputs a second clock signal (e.g., second clock signal CKB_M) as an oscillating signal in response to the second event. In some embodiments, second clock signal CKB_M has a second clock period T2 that equals (T1−ΔT). At stage 335, the phase of second clock signal CKB_M lags behind the phase of first clock signal CKA_M, and clock gating circuit 250 and counter 260 thus remain activated.

At stage 340, after Tsense/ΔT cycles, the phase of second clock signal CKB_M catches up and then leads ahead of the phase of first clock signal CKA_M. At Stage 345, in response to the updated phase relationship of first clock signal CKA_M and second clock signal CKB_M, phase detector 230 outputs detection signal HITB at the second logic state (e.g., HIGH) indicating that the phase of first clock signal CKA_M lags behind the phase of second clock signal CKB_M.

At stage 350, detection signal HITB at the second logic state (e.g., HIGH) would in turn deactivate clock gating circuit 250. At stage 350, clock gating circuit 250 sets count clock signal CKC to a fixed logic state to cause no action at counter 260. At stage 355, counter 260 stops. The counter output (e.g., count value TDC_OUT) is read as the conversion result. In some embodiments, count value TDC_OUT represents a ratio between time difference Tsense and period difference ΔT. In some embodiments, time difference Tsense is determined based on TDC_OUT×ΔT. In some embodiments, ΔT also represents a time-domain resolution of the time-to-digital conversion device, and the count value range of counter 260 corresponds to a measurable range of the time-to-digital conversion device.

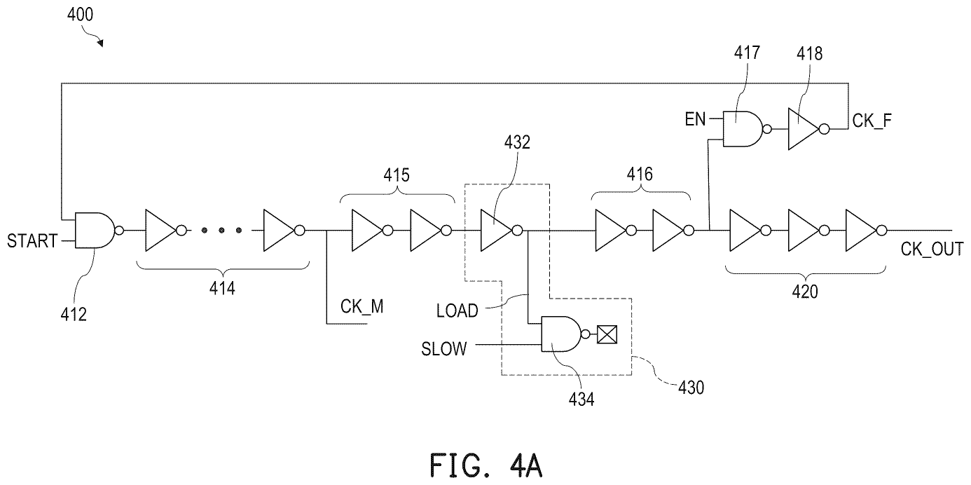

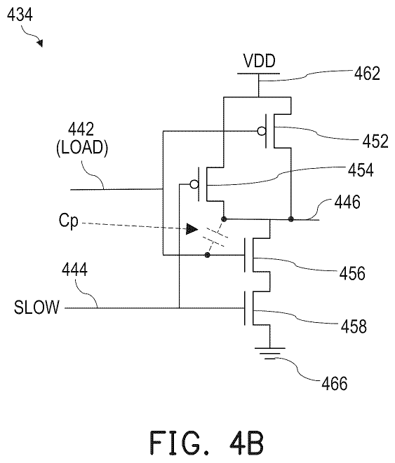

FIG. 4A is a circuit diagram of an oscillator 400, which is a ring oscillator, in accordance with some embodiments. In some embodiments, a hardware configuration of oscillator 400 is a non-limiting example usable to implement first oscillator 210 and/or second oscillator 220 in FIG. 2.

Oscillator 400 includes a first NAND gate 412 as an input stage, a first set of inverters 414, a second set of inverters 415, a third set of inverters 416, a second NAND gate 417, and an inverter 418. Oscillator 400 further includes a buffer circuit 420 after the third set of inverters 416 and a delay circuit 430 between the second set of inverters 415 and the third set of inverters 416. In some embodiments, buffer circuit 420 includes one or more inverters. In this example, delay circuit 430 includes a driving stage 432 (including one or more inverters, such as one inverter in this example) and a third NAND gate 434. In FIG. 4A, first NAND gate 412, the first set of inverters 414, the second set of inverters 415, driving stage 432 of delay circuit 430, the third set of inverters 416, second NAND gate 417, and inverter 418 are electrically coupled one after another as a loop of K inverting stages, K being an odd, positive integer. In some embodiments, the signal at an output terminal of the first set of inverters 414 is output by oscillator 400 as a clock signal CK_M.

In some embodiments, first NAND gate 412 includes a first input terminal configured to receive a feedback clock signal CK_F from inverter 418, and a second input terminal configured to receive a reference signal START. In some embodiments, in response to reference signal START being at the first logic state (e.g., LOW), first NAND gate 412 outputs the second logic state (e.g., HIGH) and thus effectively deactivates oscillator 400. In some embodiments, in response to reference signal START being at the second logic state (e.g., HIGH), first NAND gate 412 outputs at the output terminal thereof the inverse of feedback clock signal CK_F.

In some embodiments, second NAND gate 417 includes a first input terminal electrically coupled to an output terminal of the third set of inverters 416, and a second input signal configured to receive an enabling signal EN. In some embodiments, in response to enabling signal EN being at the first logic state (e.g., LOW), second NAND gate 417 outputs the second logic state (e.g., HIGH) thus effectively deactivates oscillator 400. In some embodiments, in response to enabling signal EN being at the second logic state (e.g., HIGH), second NAND gate 417 outputs at the output terminal thereof the inverse of the signal from the output terminal of the third set of inverters 416. In some embodiments, second NAND gate 417 is replaced by an inverter, and enabling signal EN is omitted.

In some embodiments, buffer circuit 420 is configured to output a buffered clock signal CK_OUT, which has the same frequency and period as clock signal CK_M. In some embodiments, buffer circuit 420 provides buffered clock signal CK_OUT a greater driving capability than clock signal CK_M with minimized interference to the loop of K inverting stages of oscillator 400.

In some embodiments, delay circuit 430 is configured to introduce an adjustable delay to the loop of K inverting stages of oscillator 400. In this example, third NAND gate 434 is illustrated as a non-limiting example. In some embodiments, a NOR gate is used in lieu of third NAND gate 434.

In this example, third NAND gate 434 includes a first input terminal (labeled as “LOAD” terminal) coupled to an output terminal of driving stage 432, a second input terminal configured to receive a slow down control signal SLOW, and an output terminal that is not electrically coupled to other circuitry. In some embodiments, in response to slow down control signal SLOW being at the first logic state (e.g., LOW), the first input terminal exhibits a first equivalent load capacitance. In some embodiments, in response to slow down control signal SLOW being at the second logic state (e.g., HIGH), the first input terminal exhibits a second equivalent load capacitance that is greater than the first equivalent load capacitance.

In one example in which first oscillator 210 is based on oscillator 400, reference signal START and the corresponding terminal in FIG. 4A correspond to first reference signal START1 and the corresponding terminal in FIG. 2; clock signal CK_M and the corresponding terminal in FIG. 4A correspond to first clock signal CKA_M and the corresponding terminal in FIG. 2, buffered clock signal CK_OUT and the corresponding terminal in FIG. 4A correspond to first buffered clock signal CKA_OUT and the corresponding terminal in FIG. 2, and slow down control signal SLOW and the corresponding terminal in FIG. 4A correspond to first slow down control signal SLOW1 and the corresponding terminal in FIG. 2.

FIG. 4B is a circuit diagram of NAND gate 434 in delay circuit 430 in FIG. 4A as a non-limiting example, in accordance with some embodiments. In FIG. 4B, NAND gate 434 includes a first input terminal 442, which is also labeled as “LOAD” in FIG. 4A. NAND gate 434 includes a second input terminal 444 configured to receive slow down control signal SLOW, and an output terminal 446 that is not electrically coupled to other circuitry outside NAND gate 434.

NAND gate 434 includes a first p-type transistor 452, a second p-type transistor 454, a first n-type transistor 456, and a second n-type transistor 458. A first drain/source terminal of first p-type transistor 452 and a first drain/source terminal of second p-type transistor 454 are electrically coupled to a first power supply node configured to carry a first power supply voltage (e.g., VDD). A second drain/source terminal of first p-type transistor 452, a second drain/source terminal of second p-type transistor 454, and a first drain/source terminal of first n-type transistor 456 are electrically coupled to output terminal 446 of NAND gate 434. A second drain/source terminal of first n-type transistor 456 is electrically coupled to a first drain/source terminal of second n-type transistor 458. A second drain/source terminal of second n-type transistor 458 is electrically coupled to a second power supply node configured to carry a second power supply voltage (e.g., VSS or ground). A gate terminal of first p-type transistor 452 and a gate terminal of first n-type transistor 456 are electrically coupled to first input terminal 442 of NAND gate 434. A gate terminal of second p-type transistor 454 and a gate terminal of second n-type transistor 458 are electrically coupled to second input terminal 444 of NAND gate 434.

In this example, in response to slow down control signal SLOW being at the first logic state (e.g., LOW), second p-type transistor 454 is on and second n-type transistor 458 is off, and a load capacitance observable at first input terminal 442 is primarily based on the parasitic capacitance (represented by a capacitor having capacitance Cp) between the first input terminal 442 and the output terminal 446. Also, in response to slow down control signal SLOW being at the second logic state (e.g., HIGH), second p-type transistor 454 is off and second n-type transistor 458 is on, and a load capacitance observable at first input terminal 442 is based on amplifying the parasitic capacitance (e.g., capacitance Cp) by Miller effect, which is effectively (1+M)×Cp, M being the gain from the output terminal 446 to the first input terminal 442.

In this example, the load difference between slow down control signal SLOW being at the first logic state and the second logic state is M×Cp. In some embodiments, an oscillator based on oscillator 400 with a load capacitance Cp and another oscillator based on oscillator 400 with a load capacitance (1+M)×Cp would have different clock periods, and the difference of clock periods is determinable based on the load difference M×Cp.

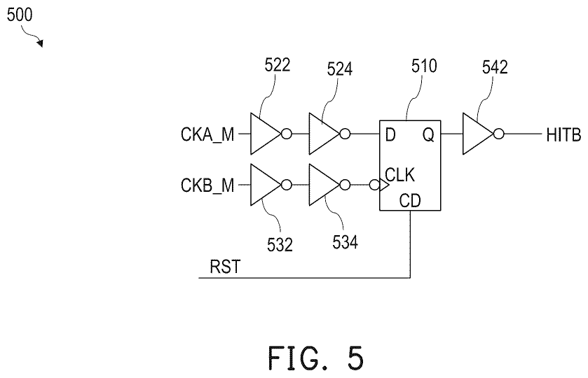

FIG. 5 is a circuit diagram of a phase detector 500, in accordance with some embodiments. In some embodiments, phase detector 500 is a non-limiting example of phase detector 230 in FIG. 2.

In FIG. 5, phase detector 500 includes a D-type flip flop 510, a first buffer stage including inverters 522 and 524 coupled in series, a second buffer stage including inverters 532 and 534 coupled in series, and an output stage including an inverter 542. In some embodiments, inverters 522 and 524 are configured to buffer a first clock signal (e.g., first clock signal CKA_M) from a first oscillator (e.g., first oscillator 210), and inverters 532 and 534 are configured to buffer a second clock signal (e.g., second clock signal CKB_M) from a second oscillator (e.g., second oscillator 220).

In this example, D-type flip flop 510 includes a D terminal, a CLK terminal, a Q terminal, and a CD terminal. In some embodiments, the D terminal of D-type flip flop 510 is configured to receive a first signal that is from the first buffer stage and corresponds to first clock signal CKA_M. In some embodiments, the CLK terminal of D-type flip flop 510 is configured to receive a second signal that is inverted based on the signal from the second buffer stage and corresponds to the inversion of second clock signal CKB_M. In some embodiments, the Q terminal of D-type flip flop 510 is configured to output a third signal corresponding to detection signal HITB. In this example, inverter 542 receives the third signal from the Q terminal of D-type flip flop 510 and outputs the detection signal HITB. In some embodiments, the CD terminal of D-type flip flop 510 is configured to receive a reset signal RST, which has no impact to the operation of D-type flip flop 510 in response to reset signal RST being at the first logic state (e.g., LOW) and causes D-type flip flop 510 to reset the output at Q terminal of D-type flip flop 510 in response to reset signal RST being at the second logic state (e.g., HIGH).

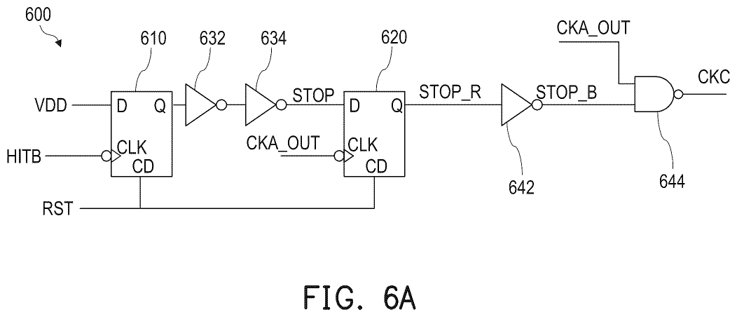

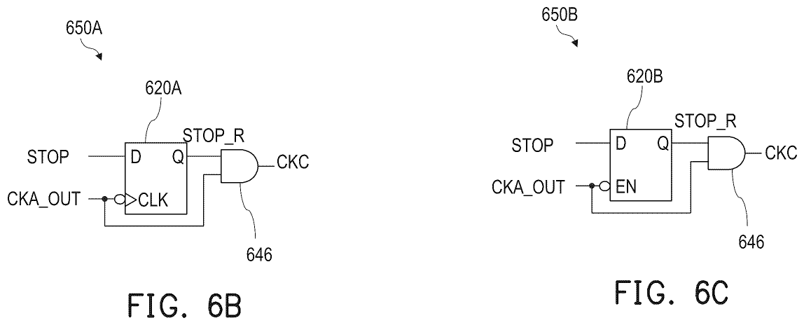

FIG. 6A is a circuit diagram of a clock gating circuit example 600, in accordance with some embodiments. In some embodiments, clock gating circuit 600 is a non-limiting example of clock gating circuit 250 in FIG. 2.

In FIG. 6A, clock gating circuit 600 includes a first D-type flip flop 610, a second D-type flip flop 620, a first buffer stage including inverters 632 and 634 coupled in series, a second buffer stage including an inverter 642, and an output stage including a NAND gate 644. In this example, each one of first D-type flip flop 610 and second D-type flip flop 620 includes a D terminal, a CLK terminal, a Q terminal, and a CD terminal. In some embodiments, the D terminal of first D-type flip flop 610 is configured to receive a supply voltage (e.g., VDD) that represent the second logic state (e.g., HIGH). In some embodiments, the CLK terminal of first D-type flip flop 610 is configured to receive a signal that is inverted based on detection signal HITB. In some embodiments, the CD terminal of first D-type flip flop 610 is configured to receive a reset signal RST, which has no impact to the operation of first D-type flip flop 610 in response to reset signal RST being at the first logic state (e.g., LOW) and causes D first D-type flip flop 610 to reset the output at Q terminal of first D-type flip flop 610 in response to reset signal RST being at the second logic state (e.g., HIGH). In some embodiments, inverters 632 and 634 are configured to buffer the output signal from the Q terminal of first D-type flip flop 610 and to provide the buffered output signal (labeled as “STOP”) to second D-type flip flop 620.

In some embodiments, the D terminal of second D-type flip flop 620 is configured to receive the buffered output signal STOP from inverter 634. In some embodiments, the CLK terminal of second D-type flip flop 620 is configured to receive first buffered clock signal CKA_OUT from a first oscillator (e.g., the first oscillator 210). In some embodiments, the CD terminal of second D-type flip flop 620 is configured to receive the reset signal RST, which has no impact to the operation of second D-type flip flop 620 in response to reset signal RST being at the first logic state (e.g., LOW) and causes second D-type flip flop 620 to reset the output at Q terminal of second D-type flip flop 620 in response to reset signal RST being at the second logic state (e.g., HIGH). In some embodiments, the Q terminal of second D-type flip flop 620 is configured to output a signal STOP_R based on the signal STOP and first buffered clock signal CKA_OUT.

In this example, inverter 642 receives the signal STOP_R and outputs an inverted signal STOP_B. In some embodiments, NAND gate 644 includes a first input terminal configured to receive first buffered clock signal CKA_OUT and a second input terminal configured to receive signal STOP_B. In some embodiments, in response to signal STOP_B being at the first logic state (e.g., LOW), NAND gate 644 outputs at the output terminal thereof the second logic state (e.g., HIGH) as counter clock signal CKC (e.g., a non-oscillating signal). In some embodiments, in response to signal STOP_B being at the second logic state (e.g., HIGH), NAND gate 644 outputs at the output terminal thereof the inverse of first buffered clock signal CKA_OUT as counter clock signal CKC (e.g., an oscillating signal).

In some other embodiments, first clock signal CKA_M, second clock signal CKB_M, or a second buffered clock signal based on second clock signal CKB_M are useable in lieu of first buffered clock signal CKA_OUT.

FIG. 6B is a circuit diagram of a variation example 650A based on the clock gating circuit 600 in FIG. 6A, in accordance with some embodiments. In some embodiments, the combination of second D-type flip flop 620, inverter 642, and NAND gate 644 is replaceable by variation example 650A.

In FIG. 6B, variation example 650A includes a D-type flip flop 620A and an AND gate 646. In this example, D-type flip flop 620A includes a D terminal, a CLK terminal, and a Q terminal. In some embodiments, the D terminal of D-type flip flop 620A is configured to receive the signal STOP. In some embodiments, the clock terminal of D-type flip flop 620A is configured to receive first buffered clock signal CKA_OUT from a first oscillator (e.g., the first oscillator 210). In some embodiments, the Q terminal of D-type flip flop 620A is configured to output the signal STOP_R based on the signal STOP and first buffered clock signal CKA_OUT.

In FIG. 6B, a first input terminal of AND gate 646 is configured to receive the signal STOP_R, and a second input terminal of AND gate 646 is configured to receive first buffered clock signal CKA_OUT. In this example, an output terminal of AND gate 646 is configured to output counter clock signal CKC.

FIG. 6C is a circuit diagram of a variation example 650B based on the clock gating circuit 600 in FIG. 6A, in accordance with some embodiments. In some embodiments, the combination of second D-type flip flop 620, inverter 642, and NAND gate 644 is replaceable by variation example 650A.

In FIG. 6C, variation example 650B includes a D-type latch 620B and an AND gate 646. In this example, D-type latch 620B includes a D terminal, an EN terminal, and a Q terminal. In some embodiments, the D terminal of D-type latch 620B is configured to receive the signal STOP. In some embodiments, the EN terminal of D-type latch 620B is configured to receive first buffered clock signal CKA_OUT from a first oscillator (e.g., the first oscillator 210). In some embodiments, the Q terminal of D-type latch 620B is configured to output the signal STOP_R based on the signal STOP and first buffered clock signal CKA_OUT.

In FIG. 6C, a first input terminal of AND gate 646 is configured to receive the signal STOP_R, and a second input terminal of AND gate 646 is configured to receive first buffered clock signal CKA_OUT. In this example, an output terminal of AND gate 646 is configured to output counter clock signal CKC.

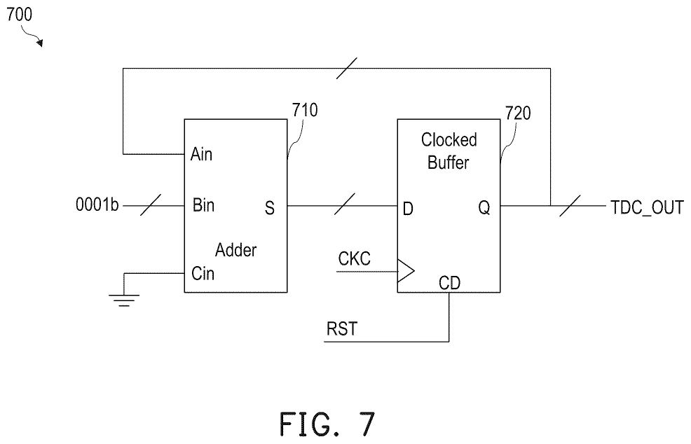

FIG. 7 is a block diagram of a counter example 700, in accordance with some embodiments. In some embodiments, counter 700 is a non-limiting example of counter example 260 in FIG. 2.

In FIG. 7, counter 700 includes an N-bit adder 710 and an N-bit clocked buffer 720. In some embodiments, N-bit adder 710 corresponds to an N-bit carry ripple adder and includes a first N-bit input port Ain, a second N-bit input port Bin, a carry-in terminal Cin, and an N-bit output port S. In some embodiments, N-bit clocked buffer 720 corresponds to a collection of N D-type flip flops and includes an N-bit input port D, an N-bit output port Q, a clock terminal (depicted with a triangle mark), and a CD terminal. In some embodiments, the CD terminal of N-bit clocked buffer 720 is configured to reset the binary value at N-bit output port Q based on a reset signal RST. In some embodiments, N-bit clocked buffer 720 is configured to update the binary value at N-bit output port Q with the binary value at N-bit input port D in response to a counter clock signal CKC at the clock terminal.

In this example, N-bit output port Q of N-bit clocked buffer 720 is configured to carry count value TDC_OUT, and first N-bit input port Ain of N-bit adder 710 is configured to receive count value TDC_OUT from N-bit output port Q of N-bit clocked buffer 720. In this example, second N-bit input port Bin is configured to receive a binary value 0001b, and carry-in terminal Cin is coupled to a supply voltage (e.g., VSS or ground) representing a binary value 0b. in some embodiments, N-bit output port S is configured to output a binary value based on a summation of the binary values at first N-bit input port Ain, second N-bit input port Bin, and carry-in terminal Cin. N-bit input port D of N-bit clocked buffer 720 receives the binary value from N-bit output port S of N-bit adder 710.

In operation, in response to counter clock signal CKC transitioning from the first logic state (e.g., LOW) to the second logic state (e.g., HIGH), N-bit clocked buffer 720 updates count value TDC_OUT at N-bit output port Q based on the output value of N-bit adder 710. In response to the updated count value TDC_OUT, N-bit adder 710 updates the digital value at N-bit output port S by adding the updated count value TDC_OUT (the value at first N-bit input port Ain) and 1 (the value at second N-bit input port Bin). The updated digital value at N-bit output port S will be used to update count value TDC_OUT at N-bit output port Q next time counter clock signal CKC transitions from the first logic state (e.g., LOW) to the second logic state (e.g., HIGH).

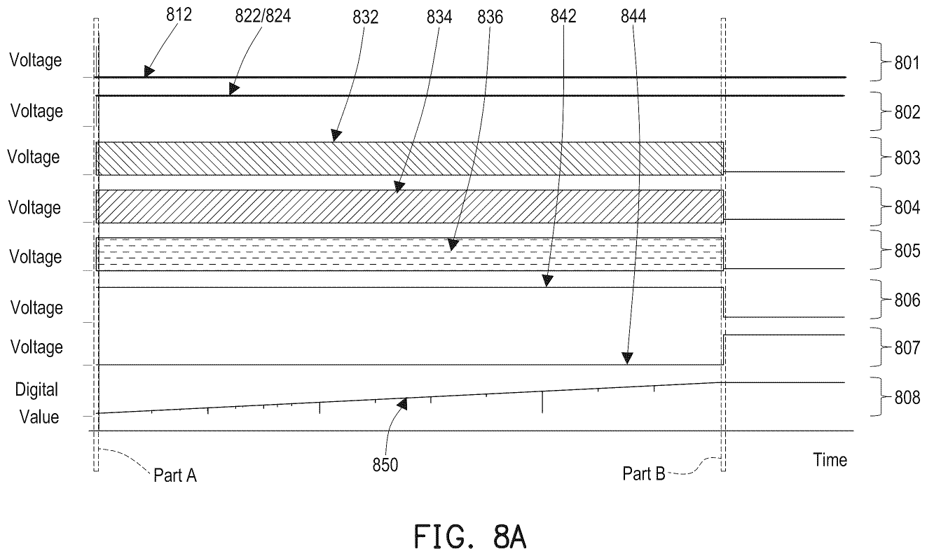

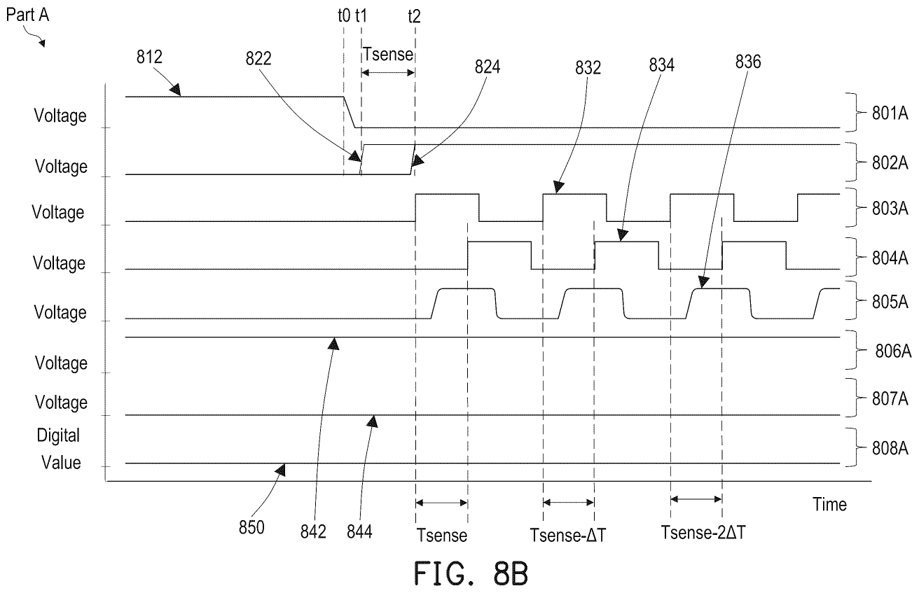

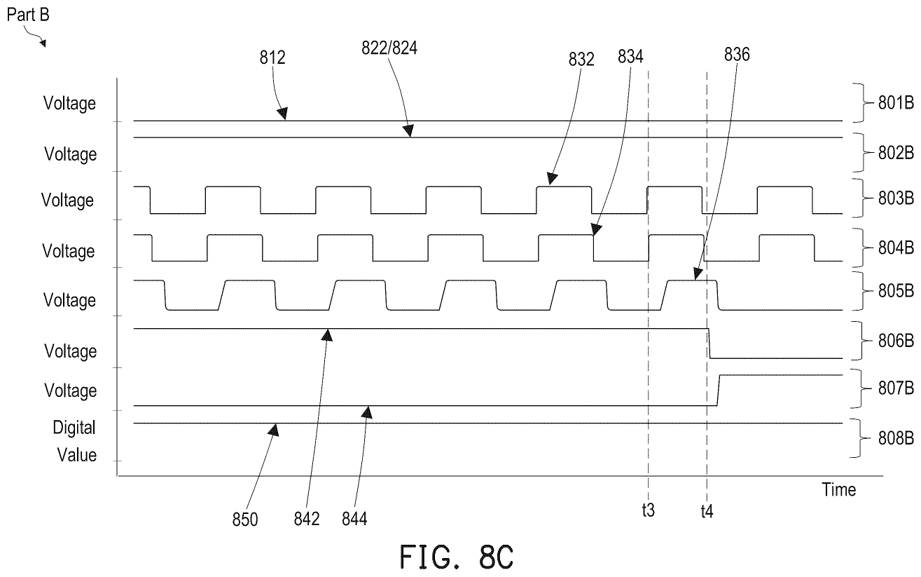

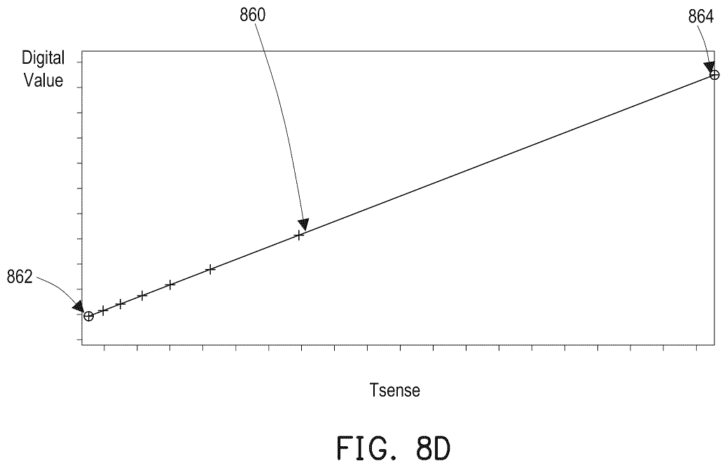

FIGS. 8A-8D are diagrams of signal waveforms and/or digital values of a time-to-digital conversion session example by a time-to-digital conversion device that is based on the examples in FIGS. 2-6A and 7, in accordance with some embodiments.

FIG. 8A includes charts 801-808. In charts 801-807, time is represented by the horizontal axes, and voltage levels of various signals are represented by the vertical axes. In chart 808, time is represented by the horizontal axis, and digital value is represented by the vertical axes.

Chart 801 includes a waveform 812 corresponding to the waveform of reset signal RST in FIGS. 5, 6A, and 7. Chart 802 includes a waveform 822 corresponding to the waveform of first reference signal START1 in FIG. 2, and a waveform 824 corresponding to the waveform of second reference signal START2 in FIG. 2. Chart 803 includes a waveform 832 corresponding to the waveform of first clock signal CKA_M in FIGS. 2 and 5. Chart 804 includes a waveform 834 corresponding to the waveform of second clock signal CKB_M in FIGS. 2 and 5. Chart 805 includes a waveform 836 corresponding to the waveform of count clock signal CKC in FIGS. 2, 6A, and 7. Chart 806 includes a waveform 842 corresponding to the waveform of detection signal HITB in FIGS. 2, 5, and 6A. Chart 807 includes a waveform 844 corresponding to the waveform of buffered output signal STOP in FIG. 6A. Chart 808 includes a waveform 850 corresponding to the waveform of count value TDC_OUT in FIGS. 2 and 7.

In FIG. 8A, first clock signal CKA_M (waveform 832), second clock signal CKB_M (waveform 834), and count clock signal CKC (waveform 836) are oscillating between a high voltage level (e.g., corresponding to a logic state of HIGH) and a low voltage level (e.g., corresponding to a logic state of LOW) in response to first reference signal START1 (waveform 822) and second reference signal START2 (waveform 824) transition from a low voltage level to a high voltage level. In FIG. 8A, count value TDC_OUT (waveform 850) increases while a phase of second reference signal START2 lags behind a phase of first reference signal START1. In FIG. 8A, count value TDC_OUT (waveform 850) stops to increase, and first clock signal CKA_M (waveform 832), second clock signal CKB_M (waveform 834), and count clock signal CKC (waveform 836) stays at a fixed logic state (e.g., represented by the low voltage level), after detection signal HITB (waveform 842) and buffered output signal STOP (waveform 844) indicate that the phase of first reference signal START1 lags behind the phase of second reference signal START2.

Portions of charts 801-808 within Part A are further illustrated in FIG. 8B, and portions of charts 801-808 within Part B are further illustrated in FIG. 8C.

FIG. 8B is an enlarged view of Part A in FIG. 8A. FIG. 8B includes charts 801A-808A corresponding to portions of charts 801-808 within Part A. In FIG. 8B, waveforms that are the same as those in FIG. 8A are given the same reference numbers.

In FIG. 8B, prior to time t0, reset signal RST (waveform 812) is at the high voltage level (e.g., HIGH) for resetting various components of a time-to-digital conversion device (e.g., time-to-digital conversion device 200), which corresponds to stage 310 in FIG. 3. At time t0, reset signal RST (waveform 812) transitions from the high voltage level (e.g., HIGH) to the low voltage level (e.g., LOW) to allow the time-to-digital conversion device to operate in response to various other signals.

At time t1, first reference signal START1 (waveform 822) transitions from the low voltage level (e.g., LOW) to the high voltage level (e.g., HIGH), which corresponds to stage 315 in FIG. 3. In response to the transition and corresponding to stage 320 in FIG. 3, a first oscillator (e.g., first oscillator 210) starts to output first clock signal CKA_M (waveform 832), after an inherent delay, as an oscillating signal transitioning between the low voltage level and the high voltage level. Also, a clock counter (e.g., clock counter 240) is activated by first clock signal CKA_M, as indicated by count clock signal CKC (waveform 836) and corresponding to stage 325 in FIG. 3.

At time t2, second reference signal START2 (waveform 824) transitions from the low voltage level (e.g., LOW) to the high voltage level (e.g., HIGH), which corresponds to stage 330 in FIG. 3. The transition of second reference signal START2 is delayed by a time difference Tsense than the transition of first reference signal START1 (e.g., t2−t1=Tsense). In response to the transition of second reference signal START2 and corresponding to stage 335 in FIG. 3, a second oscillator (e.g., second oscillator 220) starts to output second clock signal CKB_M (waveform 834), after an inherent delay, as an oscillating signal transitioning between the low voltage level and the high voltage level.

In some embodiments, first clock signal CKA_M has a first clock period T1, second clock signal CKB_M has a second clock period T2 that is less than first clock period T1 by a period difference ΔT. In FIG. 8B, a phase of second clock signal CKB_M starts lagging behind a phase of first clock signal CKA_M. In FIG. 8B, the phase difference between second clock signal CKB_M and first clock signal CKA_M is reduced by period difference ΔT every clock cycle of first clock signal CKA_M or second clock signal CKB_M. In this example, count clock signal CKC (waveform 836) and first clock signal CKA_M have the same frequency. As such, the clock counter counts the clock cycles of count clock signal CKC representing a number of clock cycles of first clock signal CKA_M has passed.

FIG. 8C is an enlarged view of Part B in FIG. 8A. FIG. 8C includes charts 801B-808B corresponding to portions of charts 801-808 within Part B. In FIG. 8C, waveforms that are the same as those in FIG. 8A are given the same reference numbers.

In FIG. 8C, at time t3 after Tsense/ΔT cycles from the time first oscillator is activated, the phase of second clock signal CKB_M (waveform 834) catches up and starts to lead ahead of the phase of first clock signal CKA_M (waveform 832), which corresponds to stage 340 in FIG. 3. At time t4, a phase detector (e.g., phase detector 230) detects the change of the phase relationship between first clock signal CKA_M and second clock signal CKB_M and outputs detection signal HITB (waveform 842) that transitions from the high voltage level (e.g., HIGH) to the low voltage level (e.g., LOW), which corresponds to stage 345 in FIG. 3.

In response to detection signal HITB (waveform 842) transitioning from the high voltage level to the low voltage level and as corresponding to stage 350 in FIG. 3, buffered output signal STOP (waveform 844) transitions from the low voltage level to the high voltage level, which in turn deactivates a clock gating circuit (e.g., clock gating circuit 250) that outputs count clock signal CKC (waveform 836). Afterwards, the digital value of count value TDC_OUT (waveform 850) is to be read as the conversion result, which corresponds to stage 355 in FIG. 3.

FIG. 8D is a diagram of digital values of count value TDC_OUT (waveform 850) versus the time difference (e.g., Tsense) between first reference signal START1 and second reference signal START2 based on the example in FIG. 8A, in accordance with some embodiments. In FIG. 8D, time difference Tsesne is represented by the horizontal axis, and digital value is represented by the vertical axes.

In this non-limiting example, time difference Tsesne and the digital value have a linear, proportional relationship as indicated by curve 860. In this example, data point 862 represents count value TDC_OUT having a digital value of 476 in response to a time difference Tsesne being 45.2531 picoseconds (ps). In this example, data point 864 represents count value TDC_OUT having a digital value of 2876 in response to a time difference Tsesne being 235.4562 ps. Accordingly, in this non-limiting example, the resolution for measuring time difference Tsesne is 79.4 fs (per unit digital value).

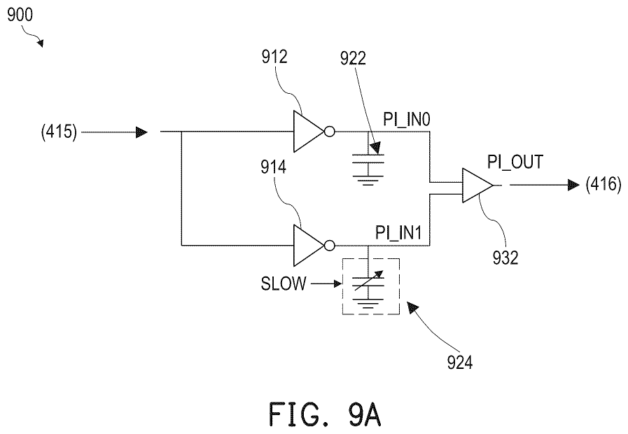

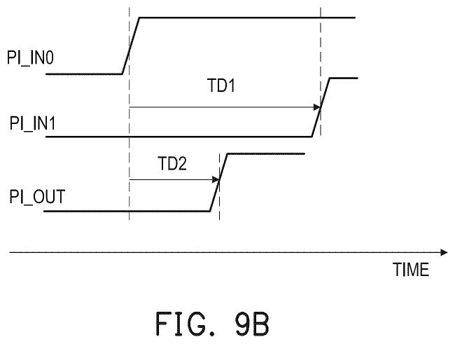

FIG. 9A is a circuit diagram of a delay circuit example 900 based on a phase interpolator, in accordance with some embodiments. In some embodiments, delay circuit 900 is usable as an alternative embodiment of delay circuit 430 in FIG. 4A. In FIG. 9A, delay circuit 900 includes inverters 912 and 914, capacitors 922 and 924, and a phase interpolator 932. The input terminals of inverters 912 and 914 are suitable to be electrically coupled to the second set of inverters 415 in FIG. 4A; and the output terminal of phase interpolator 932 is suitable to be electrically coupled to the third set of inverters 416 in FIG. 4A.

In FIG. 9A, capacitor 922 has one terminal coupled to a power supply node configured to carry a power supply voltage (e.g., VSS or ground) and another terminal electrically coupled to an output terminal of inverter 912 and an input terminal of phase interpolator 932. Also, capacitor 924 has one terminal coupled to a power supply node configured to carry a power supply voltage (e.g., VSS or ground) and another terminal electrically coupled to an output terminal of inverter 912 and another input terminal of phase interpolator 932. In some embodiments, capacitor 922 has a capacitance of C1. In some embodiments, capacitor 924 has a capacitance of C2 in response to a slow down control signal SLOW being at a first logic state (e.g., LOW) and a capacitance of C2+ΔC in response to slow down control signal SLOW being at a second logic state (e.g., HIGH). In some embodiments, capacitance C1 and capacitance C2 are set to be the same or within 10% of variation. In some embodiments, capacitor 922 is omitted, and capacitance C1 is deemed to be zero.

In FIG. 9A, the signal at an input terminal of phase interpolator 932 coupled to the output terminal of inverter 912 is labeled as PI_IN0; and the signal at the other input terminal of phase interpolator 932 coupled to the output terminal of inverter 914 is labeled as PI_IN1. Also, the signal at the output terminal of phase interpolator 932 is labeled as PI_OUT. In some embodiments, phase interpolator 932 is configured to determine a first time delay of a signal transition of signal PI_IN1 with respect to a signal transition of signal PI_IN0, and output signal PI_OUT that has a signal transition and a second time delay with respect to the signal transition of signal PI_IN0. In some embodiments, the second time delay is a fraction of the first time delay.

FIG. 9B is a diagram of various signals of delay circuit 900 in FIG. 9A, in accordance with some embodiments. In FIG. 9B, time is represented by the horizontal axis. In FIG. 9B, a signal transition of signal PI_IN1 has a first delay TD1 with respect to a signal transition of signal PI_IN0. In FIG. 9B, a signal transition of signal PI_OUT has a second delay TD2 with respect to the signal transition of signal PI_IN0.

Accordingly, delay circuit 900 is configurable to further reduce a period difference ΔT between two oscillators without further reducing the difference in corresponding load capacitance values of the two oscillators. In some embodiments, the period difference ΔT based on second delay TD2 is in the range of tens of fs for a finer resolution of the resulting time-to-digital conversion device that that based on first delay TD1.

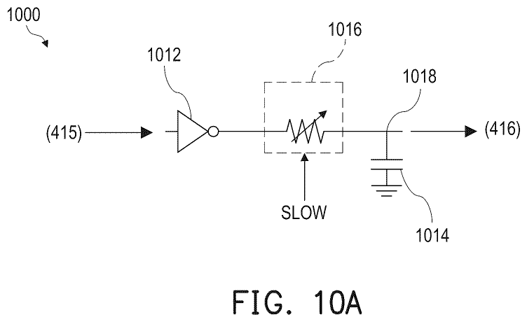

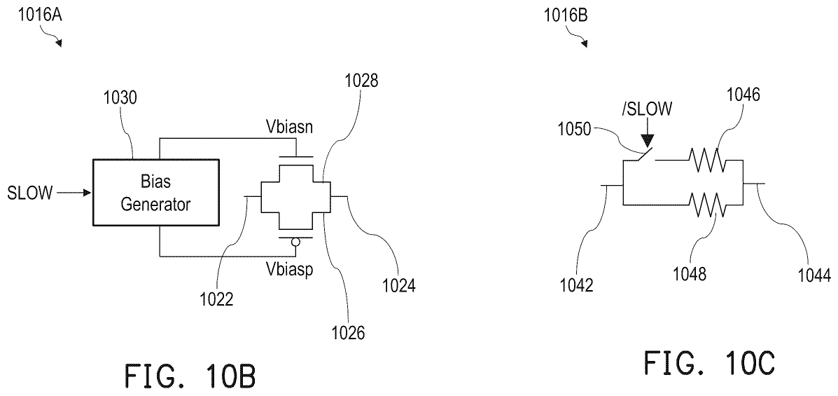

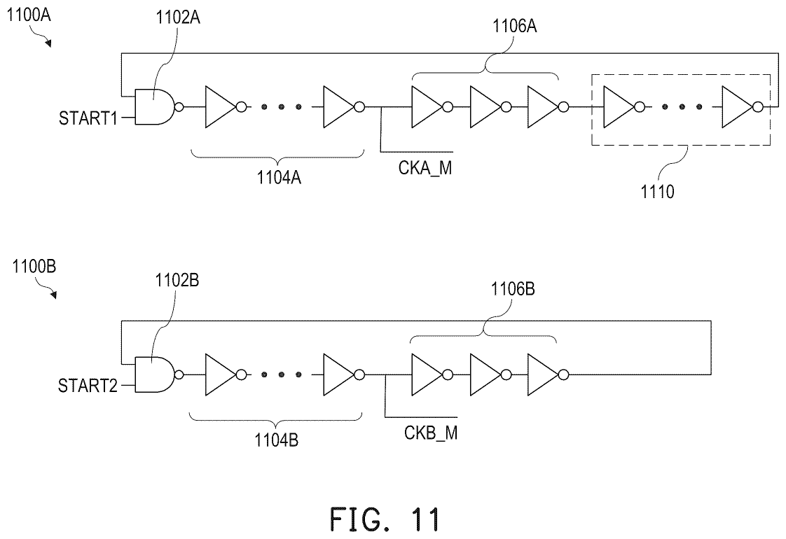

FIG. 10A is a circuit diagram of a delay circuit example 1000 based on an adjustable load resistance, in accordance with some embodiments. In some embodiments, delay circuit 1000 is usable as another alternative embodiment of delay circuit 430 in FIG. 4A. In FIG. 10A, delay circuit 1000 includes an inverter 1012, a capacitor 1014, and an adjustable resistor 1016. The input terminal of inverter 1012 is suitable to be electrically coupled to the second set of inverters 415 in FIG. 4A; and an output node 1018 of delay circuit 1000 is suitable to be electrically coupled to the third set of inverters 416 in FIG. 4A.

In FIG. 10A, capacitor 1014 has one terminal coupled to a power supply node configured to carry a power supply voltage (e.g., VSS or ground) and another terminal electrically coupled to output node 1018. Also, adjustable resistor 1016 has one terminal electrically coupled to an output terminal of inverter 1012 and another terminal electrically coupled to the output node 1018. In some embodiments, a time delay between the input terminal of inverter 1012 and output node 1018 is determinable based on the resistance of adjustable resistor 1016, where the greater the resistance value of adjustable resistor 1016, the greater delay imposed between the second set of inverters 415 and the third set of inverters 416.

FIG. 10B is a circuit diagram of a first adjustable resistor example 1016A usable as adjustable resistor 1016 in FIG. 10A, in accordance with some embodiments. First adjustable resistor 1016A includes a first terminal 1022 and a second terminal 1024 corresponding to two terminals of adjustable resistor 1016 in FIG. 10A. First adjustable resistor 1016A includes a p-type transistor 1026, an n-type transistor 1028, and a bias generator 1030. A first drain/source terminal of p-type transistor 1026 and a first drain/source terminal of n-type transistor 1028 are electrically coupled to first terminal 1022; and a second drain/source terminal of p-type transistor 1026 and a second drain/source terminal of n-type transistor 1028 are electrically coupled to second terminal 1024.

In some embodiments, bias generator 1030 is configured to generate a first biasing voltage Vbiasp supplied to a gate terminal of p-type transistor 1026 and a second biasing voltage Vbiasn supplied to a gate terminal of n-type transistor 1028. In some embodiments, bias generator 1030 is configured to output suitable voltage levels at first biasing voltage Vbiasp and second biasing voltage Vbiasn in response to slow down control signal SLOW in order to adjust a resistance value between first terminal 1022 and second terminal 1024.

FIG. 10C is a circuit diagram of a second adjustable resistor example 1016B usable as adjustable resistor 1016 in FIG. 10A, in accordance with some embodiments. Second adjustable resistor 1016B includes a first terminal 1042 and a second terminal 1044 corresponding to two terminals of adjustable resistor 1016 in FIG. 10A. Second adjustable resistor 1016B includes a first resistor 1046, a second resistor 1048, and a switch 1050. In this example, second resistor 1048 is electrically coupled between first terminal 1042 and second terminal 1044; and first resistor 1046 has one end electrically coupled to second terminal 1044 and another end electrically coupled to switch 1050.

In FIG. 10C, switch 1050 is configured to electrically couple first resistor 1046 to first terminal 1042 or electrically decouple first resistor 1046 from first terminal 1042 in response to an inverse of slow down control signal SLOW (labeled as “/SLOW”). Accordingly, the resistance between first terminal 1042 and second terminal 1044 is adjustable based on slow down control signal SLOW.

FIG. 11 is a circuit diagram of oscillators that are configured to correspond to different clock periods, in accordance with some embodiments. In FIG. 11, a first oscillator 1100A corresponds to first oscillator 210 in FIG. 2, and a second oscillator 1100B corresponds to second oscillator 220 in FIG. 2.

In some embodiments, first oscillator 1100A is a ring oscillator and includes a NAND gate 1102A, a first set of inverters 1104A, a second set of inverters 1106A, and a third set of inverters 1110. A first input terminal of NAND gate 1102A is electrically coupled to an output terminal of third set of inverters 1110. A second input terminal of NAND gate 1102A is configured to receive a reference signal (e.g., first reference signal START1). In some embodiments, the signal at an output terminal of first set of inverters 1104A is used as an output clock signal (e.g., first clock signal CKA_M).

In some embodiments, second oscillator 1100B is a ring oscillator and includes a NAND gate 1102B, a first set of inverters 1104B, and a second set of inverters 1106B. A first input terminal of NAND gate 1102B is electrically coupled to an output terminal of second set of inverters 1106B. A second input terminal of NAND gate 1102B is configured to receive another reference signal (e.g., second reference signal START2). In some embodiments, the signal at an output terminal of first set of inverters 1104B is used as an output clock signal (e.g., second clock signal CKB_M).

In some embodiments, the hardware configurations of NAND gate 1102A, the first set of inverters 1104A, and the second set of inverters 1106A match the hardware configurations of NAND gate 1102B, the first set of inverters 1104B, and the second set of inverters 1106B. In some embodiments, the third set of inverters 1110 include M inverting stages. In some embodiments, NAND gate 1102A, the first set of inverters 1104A, the second set of inverters 1106A, and the third set of inverters 1110 are electrically coupled one after another as a loop of K+M inverting stages. In some embodiments, NAND gate 1102B, the first set of inverters 1104B, and the second set of inverters 1106B are also electrically coupled one after another as a loop of K inverting stages. In some embodiments, K is an odd, positive integer, and M is an even, positive integer.

In this example, the additional delay introduced by the third set of inverters 1110 further enlarges the time period of first clock signal CKA_M with respect to second clock signal CKB_M. In some embodiments, because no adjustable delays are available based on the hardware configurations of first oscillator 1100A and second oscillator 1100B, first slow down control signal SLOW1 and/or second slow down control signal SLOW2 as illustrated in FIG. 2 are thus omitted.

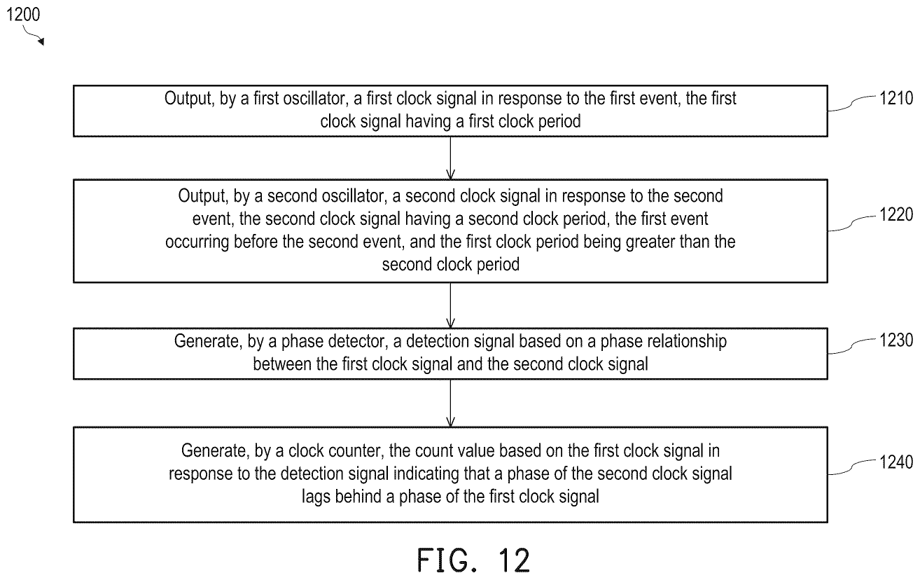

FIG. 12 is a flowchart of a method 1200 of generating a count value indicative of a time difference between a first event and a second event, in accordance with some embodiments. In some embodiments, various operations of method 1200 are performed by time-to-digital conversion device 200 in FIG. 2 in view of various implementation examples in FIGS. 3-11. As in FIG. 12, method 1200 includes blocks 1210-1240.

At block 1210, a first clock signal (e.g., first clock signal CKA_M in FIG. 2) is output by a first oscillator (e.g., first oscillator 210 in FIG. 2) in response to the first event. In some embodiments, the first clock signal has a first clock period. In some embodiments, block 1210 corresponds to at least operations of stages 315 and 320 in FIG. 3.

In some embodiments, method 1200 further includes receiving, by the first oscillator, a first reference signal (e.g., first reference signal START1 in FIG. 2), where the first event corresponds to the first reference signal changing from a first logic state (e.g., LOW) to a second logic state (e.g., HIGH). In some embodiments, method 1200 further includes deactivating the first oscillator based on the first reference signal being at the first logic state, and/or activating the first oscillator based on the first reference signal being at the second logic state.

At block 1220, a second clock signal (e.g., second clock signal CKB_M in FIG. 2) is output by a second oscillator (e.g., second oscillator 220 in FIG. 2) in response to the second event. In some embodiments, the second clock signal has a second clock period. In some embodiments, the first event occurs before the second event (e.g., by a time difference Tsense). In some embodiments, the first clock period is greater than the second clock period by a period difference ΔT. In some embodiments, block 1220 corresponds to at least operations of stages 330 and 335 in FIG. 3.

In some embodiments, method 1200 further includes receiving, by the second oscillator, a second reference signal (e.g., second reference signal START2 in FIG. 2), where the second event corresponds to the second reference signal changing from the first logic state (e.g., LOW) to the second logic state (e.g., HIGH). In some embodiments, method 1200 further includes deactivating the second oscillator based on the second reference signal being at the first logic state, and/or activating the second oscillator based on the second reference signal being at the second logic state.

At block 1230, a detection signal (e.g., detection signal HITB in FIG. 2) is generated by a phase detector (e.g., phase detector 230 in FIG. 2) based on a phase relationship between the first clock signal and the second clock signal. In some embodiments, block 1230 corresponds to at least operations of stages 340 and 345 in FIG. 3.

At block 1240, the count value (e.g., count value TDC_OUT in FIG. 2) is generated by a clock counter (e.g., clock counter 240 in FIG. 2) based on the first clock signal in response to the detection signal indicating that a phase of the second clock signal lags behind a phase of the first clock signal. In some embodiments, block 1240 corresponds to at least a portion of operations of stages 325-345 in FIG. 3.

In some embodiments, for generating, by the clock counter, the count value, method 1200 further includes generating, by a clock gating circuit (e.g., clock gating circuit 250 in FIG. 2) of the clock counter, a count clock signal (e.g., count clock signal CKC in FIG. 2) based on the first clock signal and the detection signal. In some embodiments, method 1200 further includes generating, by a counter (e.g., counter 260 in FIG. 2), the count value based on the count clock signal. In some embodiments, the counter is an N-bit counter, where N ranges from 6 to 12, or 8 to 10. In some embodiments, the count value is an N-bit unsigned integer.

In some embodiments, method 1200 further includes setting the first oscillator, the second oscillator, or both such that the second clock period is at least 100 times the period difference ΔT between the first clock period and the second clock period. In some embodiments, the first oscillator is a first ring oscillator, and the second oscillator is a second ring oscillator. In some embodiments, method 1200 further includes setting a first configurable delay of the first oscillator based on configuring one or more of a first load capacitance, a first load resistance, or a first phase interpolator between consecutive inverting stages of the first oscillator, as illustrated in the examples in FIGS. 4A, 4B, and 9A-10C. In some embodiments, method 1200 further includes setting a second configurable delay of the second oscillator based on configuring one or more of a second load capacitance, a second load resistance, or a second phase interpolator between consecutive inverting stages of the second oscillator, as illustrated in the examples in FIGS. 4A, 4B, and 9A-10C.

In some aspects, a time-to-digital conversion device includes a first oscillator configured to output a first clock signal in response to a first event and a second oscillator configured to output a second clock signal in response to a second event. The first event occurs before the second event. The first clock signal has a first clock period, the second clock signal has a second clock period, and the first clock period being greater than the second clock period. The time-to-digital conversion device further includes a phase detector configured to generate a detection signal based on a phase relationship between the first clock signal and the second clock signal, and a clock counter configured to generate a count value based on the first clock signal in response to the detection signal indicating that a phase of the second clock signal lags behind a phase of the first clock signal. The count value is indicative of a time difference between the first event and the second event.

In some aspects, a method of generating a count value indicative of a time difference between a first event and a second event includes outputting, by a first oscillator, a first clock signal in response to the first event, and outputting, by a second oscillator, a second clock signal in response to the second event. The first event occurs before the second event. The first clock signal has a first clock period, the second clock signal has a second clock period, and the first clock period being greater than the second clock period. The method further includes generating, by a phase detector, a detection signal based on a phase relationship between the first clock signal and the second clock signal, and generating, by a clock counter, the count value based on the first clock signal in response to the detection signal indicating that a phase of the second clock signal lags behind a phase of the first clock signal.

In some aspects, an integrated circuit die includes one or more digital circuit blocks configured to output a first reference signal and a second reference signal, and a time-to-digital conversion device configured to output a count value indicative of a time difference between a first event and a second event. The time-to-digital conversion device includes a first oscillator configured to output a first clock signal in response to the first event based on the first reference signal and a second oscillator configured to output a second clock signal in response to the second event based on the second reference signal. The first event occurs before the second event. The first clock signal has a first clock period, the second clock signal has a second clock period, and the first clock period being greater than the second clock period. The time-to-digital conversion device further includes a phase detector configured to generate a detection signal based on a phase relationship between the first clock signal and the second clock signal, and a clock counter configured to generate a count value based on the first clock signal in response to the detection signal indicating that a phase of the second clock signal lags behind a phase of the first clock signal.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A time-to-digital conversion device, comprising:
a first oscillator configured to output a first clock signal responsive to a first event, the first clock signal having a first clock period;
a second oscillator configured to output a second clock signal responsive to a second event, the second clock signal having a second clock period, the first event occurring before the second event, and the first clock period being greater than the second clock period;
a phase detector configured to detect a phase relationship between the first clock signal and the second clock signal; and
a clock counter configured to count based on the second clock signal responsive to the detection of a phase of the second clock signal lagging behind a phase of the first clock signal, the count representing a time difference between the first event and the second event.

2. The time-to-digital conversion device of claim 1, wherein
the first event corresponds to a first reference signal changing from a first logic state to a second logic state, and
the second event corresponds to a second reference signal changing from the first logic state to the second logic state.

3. The time-to-digital conversion device of claim 2, wherein
the first oscillator is configured to be deactivated based on the first reference signal being at the first logic state and to be activated based on the first reference signal being at the second logic state, and
the second oscillator is configured to be deactivated based on the second reference signal being at the first logic state and to be activated based on the second reference signal being at the second logic state.

4. The time-to-digital conversion device of claim 1, wherein
the first oscillator is a first ring oscillator comprising one or more of a first load capacitance, a first load resistance, or a first phase interpolator between two consecutive inverting stages of the first oscillator and configured to set a first configurable delay of the first oscillator, and
the second oscillator is a second ring oscillator comprising one or more of a second load capacitance, a second load resistance, or a second phase interpolator between two consecutive inverting stages of the second oscillator and configured to set a second configurable delay of the second oscillator.

5. The time-to-digital conversion device of claim 4, wherein
the first load capacitance or the second load capacitance is based on a NAND gate or a NOR gate.

6. The time-to-digital conversion device of claim 1, wherein
the phase detector includes a D-type flip flop,
a D terminal of the D-type flip flop is configured to receive a first signal corresponding to the second clock signal,
a clock terminal of the D-type flip flop is configured to receive a second signal corresponding to inversion of the first clock signal, and
a Q terminal of the D-type flip flop is configured to output a third signal corresponding to the detection.

7. The time-to-digital conversion device of claim 1, wherein the clock counter comprises:
a clock gating circuit configured to generate a count clock signal based on the second clock signal and the detection; and
a counter configured to generate the count based on the count clock signal.

8. The time-to-digital conversion device of claim 7, wherein
the clock gating circuit is based on a D-type flip flop or a D-type latch, and with a NAND gate or an AND gate.

9. The time-to-digital conversion device of claim 7, wherein
the counter is an N-bit counter, and
N ranges from 6 to 12.

10. The time-to-digital conversion device of claim 1, wherein
the second clock period is at least 100 times a period difference between the first clock period and the second clock period.

11. A method of counting a time difference between a first event and a second event, comprising:
outputting, by a first oscillator, a first clock signal responsive to the first event, the first clock signal having a first clock period;
outputting, by a second oscillator, a second clock signal responsive to the second event, the second clock signal having a second clock period, the first event occurring before the second event, and the first clock period being greater than the second clock period;
detecting, by a phase detector, a phase relationship between the first clock signal and the second clock signal; and
generating, by a clock counter, the count based on the second clock signal responsive to the detection of a phase of the second clock signal lagging behind a phase of the first clock signal.

12. The method of claim 11, further comprising:
receiving, by the first oscillator, a first reference signal, the first event corresponding to the first reference signal changing from a first logic state to a second logic state, and
receiving, by the second oscillator, a second reference signal, the second event corresponding to the second reference signal changing from the first logic state to the second logic state.

13. The method of claim 12, further comprising:
deactivating the first oscillator based on the first reference signal being at the first logic state;
activating the first oscillator based on the first reference signal being at the second logic state;
deactivating the second oscillator based on the second reference signal being at the first logic state; or
activating the second oscillator based on the second reference signal being at the second logic state.

14. The method of claim 11, further comprising:
setting a first configurable delay of the first oscillator based on configuring one or more of a first load capacitance, a first load resistance, or a first phase interpolator between two consecutive inverting stages of the first oscillator, and
setting a second configurable delay of the second oscillator based on configuring one or more of a second load capacitance, a second load resistance, or a second phase interpolator between two consecutive inverting stages of the second oscillator,
wherein the first oscillator is a first ring oscillator, and the second oscillator is a second ring oscillator.

15. The method of claim 11, wherein the generating, by the clock counter, the count comprises:
generating, by a clock gating circuit of the clock counter, a count clock signal based on the second clock signal and the detection; and
generating, by a counter, the count based on the count clock signal.

16. The method of claim 15, wherein
the count is an N-bit unsigned integer, and
N ranges from 6 to 12.

17. The method of claim 11, further comprising:
setting the first oscillator, the second oscillator, or both such that the second clock period is at least 100 times a period difference between the first clock period and the second clock period.

18. An integrated circuit die, comprising:
one or more digital circuit blocks configured to output a first reference signal and a second reference signal; and
a time-to-digital conversion device configured to output a count representing a time difference between a first event and a second event, the time-to-digital conversion device comprising:
a first oscillator configured to output a first clock signal responsive to the first event based on the first reference signal, the first clock signal having a first clock period;
a second oscillator configured to output a second clock signal responsive to the second event based on the second reference signal, the second clock signal having a second clock period, the first event occurring before the second event, and the first clock period being greater than the second clock period;
a phase detector configured to detect a phase relationship between the first clock signal and the second clock signal; and
a clock counter configured to count based on the second clock signal responsive to the detection of a phase of the second clock signal lagging behind a phase of the first clock signal.

19. The integrated circuit die of claim 18, wherein
the first oscillator is a first ring oscillator comprising one or more of a first load capacitance, a first load resistance, or a first phase interpolator between two consecutive inverting stages of the first oscillator and configured to set a first configurable delay of the first oscillator, and
the second oscillator is a second ring oscillator comprising one or more of a second load capacitance, a second load resistance, or a second phase interpolator between two consecutive inverting stages of the second oscillator and configured to set a second configurable delay of the second oscillator.

20. The integrated circuit die of claim 18, wherein the clock counter comprises:
a clock gating circuit configured to generate a count clock signal based on the second clock signal and the detection; and
a counter configured to generate the count based on the count clock signal.
